(19) United States
(12) Patent Application Publication
(10) Pub. No.: US 2025/0299945 A1
(43) Pub. Date: Sep. 25, 2025

(54) METAL ENCAPSULATION OF ETCH MASK VIA SPUTTERING

(71) Applicant: Tokyo Electron Limited, Tokyo (JP)

(72) Inventors: Joshua Baillargeon, Albany, NY (US); David Eitan Barlaz, Albany, NY (US)

(21) Appl. No.: 18/614,207

(22) Filed: Mar. 22, 2024

(51) Int. Cl. H01L 21/02; C23C 14/34; C23C 14/35; H01L 21/311

(52) U.S. Cl. CPC H01L 21/02266; C23C 14/3485; C23C 14/35; H01L 21/31144

(57) ABSTRACT

A method of etching an underlying material includes performing a patterning step of patterning a nonmetal mask layer to form an etch mask that includes openings exposing the underlying material, performing a deposition step of depositing a metal shell on the etch mask and exposed surfaces of the underlying material with magnetron sputtering using a series of bipolar pulses, and performing an etch step of etching the underlying material through the openings of the etch mask after the deposition step. Each bipolar pulse of the series of bipolar pulses may include applying a higher power negative pulse to a metal target to dislodge metal atoms therefrom, and applying a positive pulse to the metal target to accelerate the metal atoms towards the etch mask.

### TECHNICAL FIELD

The present invention relates generally to systems and methods for semiconductor processing, and, in particular embodiments, to systems and methods for metal encapsulation of an etch mask used during an etching process.

### BACKGROUND

Microelectronic device fabrication typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, with plasma etching processes being an example of a dry etching process. Etching processes are used in a variety of semiconductor processing areas such as in memory manufacture.

One category of etching processes is high aspect ratio (HAR) etching, which includes processes such as high aspect ratio contact (HARC) etches for contact formation. Obtaining a high aspect ratio during etching is important for a variety of semiconductor processes such as during NAND formation (e.g., 3D-NAND), NOR gate formation, and others. One way that manufacturers are using HAR etching processes is to increase the number of transistors and other semiconductor devices per unit area, is utilizing the vertical dimension (3D). For example, in a 3D NAND memory array, charge trapping flash transistors are stacked vertically one on top of another on the sidewalls in high aspect ratio openings. In DRAM memory arrays, to increase capacitance, high aspect ratio DRAM trench capacitor openings are etched deeper and deeper into the semiconductor substrate. Through silicon vias (TSV) for stacking integrated circuit chips are fabricated by etching high aspect ratio holes completely through substrates.

Typical materials used for a hardmask when manufacturing devices that have HAR features are nonmetal masks, often consisting of or including carbon. However, these traditional hardmask materials, such as amorphous carbon (a-C) do not have high enough etch selectivity for many current HAR applications. Metal hardmask materials (including hardmask materials with metal as a prominent component) are an attractive alternative, but to this point have fallen victim to various problems, such as integration challenges and poor film quality. Therefore, improved systems and methods for increasing the selectivity of etch masks are desirable.

### SUMMARY

In accordance with an embodiment of the invention, a method of etching an underlying material includes performing a patterning step of patterning a nonmetal mask layer to form an etch mask that includes openings exposing the underlying material, performing a deposition step of depositing a metal shell on the etch mask and exposed surfaces of the underlying material with magnetron sputtering using a series of bipolar pulses, and performing an etch step of etching the underlying material through the openings of the etch mask after the deposition step.

In accordance with another embodiment of the invention, a method of etching a dielectric material includes performing a deposition step of depositing a metal shell directly on a carbon-containing etch mask by applying a series of bipolar pulses to a metal target, and performing an etch step of etching the dielectric material through openings in the carbon-containing etch mask. Each of the bipolar pulses includes applying a higher power negative pulse to the metal target to dislodge metal atoms therefrom, and applying a positive pulse to the metal target to accelerate the metal atoms towards the carbon-containing etch mask.

In accordance with still another embodiment of the invention, a bipolar pulsed magnetron sputtering system includes a chamber, a metal target disposed in the chamber, a holder configured to support a substrate that includes a nonmetal etch mask, pulse generation circuitry electrically coupled to the metal target and the holder, and processing circuitry. The pulse generation circuitry is configured to generate a series of bipolar pulses. The processing circuitry is configured to deposit a metal shell directly on the nonmetal etch mask and exposed surfaces of an underlying material using the series of bipolar pulses.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example etching process that includes patterning step, a deposition step, and an etch step where a continuous metal shell is deposited using a series of bipolar pulses during the deposition step in accordance with embodiments of the invention;

FIG. 2 schematically illustrates another example etching process that includes patterning step, a deposition step, and an etch step, where a pre-etch step is also included in accordance with embodiments of the invention;

FIG. 3 schematically illustrates still another example etching process that includes patterning step, a deposition step, and an etch step, where a chemical vapor deposition step is also included in accordance with embodiments of the invention;

FIG. 4 illustrates a qualitative timing diagram of a series of bipolar pulses that may be used during example etching processes described herein, where each bipolar pulse includes a negative pulse and a positive pulse in accordance with embodiments of the invention;

FIG. 5 illustrates a qualitative timing diagram of a series of bipolar pulses that may be used during example etching processes described herein, where a series of negative pulses is interspersed into the series of bipolar pulses e in accordance with embodiments of the invention;

FIG. 6 illustrates a qualitative timing diagram of a series of bipolar pulses that may be used during example etching processes described herein, where a series of AC pulses is interspersed into the series of bipolar pulses accordance with embodiments of the invention;

FIG. 7 illustrates an example bipolar pulsed magnetron sputtering system that can be used to perform example etching processes described herein, where the system includes pulse generation circuitry configured to generate a series of bipolar pulses in accordance with embodiments of the invention;

FIG. 8 illustrates a flowchart of an example method of etching an underlying material that includes a patterning step, a deposition step, and an etch step in accordance with embodiments of the invention; and

FIG. 9 illustrates a flowchart of an example method of etching a dielectric material that includes a deposition step and an etch step in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Nonmetal mask materials (e.g., carbon-containing materials like amorphous carbon layer (ACL), spin-on-carbon (SoC), diamond-like carbon, photoresist (PR) mask, silicon-containing materials like silicon oxide (SiO₂), silicon nitride (Si₃N₄), polysilicon, etc.) suffer from selectivity limitations during HAR processes, such as HARC etches. As a result, the achievable aspect ratio of HAR features is undesirably capped by the mask material, and there is a desire to move from carbon- and silicon-containing mask materials to metal-containing materials. However, simply replacing nonmetal masks with metal-based masks is also not an option due to integration issues, such as patterning difficulties, lack of adhesion, unwanted film stresses, possibility of contamination, additional integration steps, and others.

One possible solution is to encapsulate a nonmetal mask with a metal material (including materials with metal as a prominent component). That is, a metal shell may be formed over an existing mask, such as an ACL mask. Advantageously, such a solution retains the compatibility and patterning benefits of the nonmetal mask while gaining selectivity benefits associated with a metal mask. However, in order to prevent degradation of features during the etching process, it is important for the metal shell to be continuous (i.e., to protect feature sidewalls and maintain the mask profile) and smooth (i.e., minimal surface roughness to promote uniformity).

Conventional methods of depositing a metal shell on an existing mask include physical vapor deposition (PVD), chemical vapor deposition (CVD), and atomic layer deposition (ALD). Conventional PVD processes result in films that are neither continuous (e.g., due to shadowing) nor smooth. On the other hand, conventional CVD processes can be continuous. Yet, conventional CVD processes are also too rough. Chemical mechanical polishing (CMP) techniques can be used to smooth upper surfaces of conventional CVD metal shells, but do nothing to improve sidewall smoothness (which may be the most detrimental to the integrity of the pattern transfer). Conventional ALD techniques can also be continuous, but film roughness varies widely between different metal shell materials and precursors. Moreover, ALD processes are very slow (i.e., requiring a gas purging step between depositing each layer of atoms) resulting in a large decrease in throughput.

In accordance with embodiments herein described, the invention proposes a hybrid approach using a nonmetal etch mask and a metal shell. A nonmetal mask layer may be patterned to form the etch mask before other metal materials are deposited. The metal shell is deposited using a series of bipolar pulses (e.g., applied to a metal target as part of a bipolar pulsed magnetron sputtering technique). The metal shell may advantageously be continuous, with the ability to control the ratio of upper surface deposition relative to sidewall deposition. Additionally, the metal shell may be smooth, especially compared to conventional techniques, such as CVD methods or other PVD. Because the metal shell is a metal, includes metal components or exhibits metallic properties, such as etch resistance, the metal shell may be advantageously thin while still achieving desired mask protection. Moreover, various aspects of the series of bipolar pulses may be tuned to increase deposition rate, such as the positive pulse for accelerating ions towards the etch mask, or adding AC pulses for promoting reactive sputtering.

In various embodiments, an etching process includes a deposition step during which a metal shell (which may be a pure metal, include metal components, or may exhibit metallic properties, such as etch resistance) is deposited on a nonmetal etch mask (e.g., a carbon- or silicon-containing etch mask, like an ACL, SoC, etc.) as well as exposed surfaces of an underlying material (such as a dielectric material, like an oxide, nitride, oxynitride, or combination thereof) using a series of bipolar pulses (e.g., with magnetron sputtering). The underlying material is then etched through openings in the nonmetal etch mask during an etch step. The deposition step and the etch step may be repeated as part of a cycle to continue to deposit the metal shell and etch the underlying material.

When the deposition step is performed, the nonmetal etch mask has already been patterned. For example, the etch mask may be formed during a patterning step when a nonmetal mask layer to form the openings in the etch mask that expose the underlying material. In some embodiments, no metal is deposited before the nonmetal mask layer is patterned. In other embodiments, a metal-containing layer (which may be the same or different metal than the metal shell) is formed (e.g., using CVD) above the nonmetal mask layer and both the metal-containing layer and the nonmetal mask layer are patterned to form the etch mask. The metal shell may advantageously decrease surface roughness the metal-containing layer.

During the deposition step, the series of bipolar pulses may be applied to a metal target (may be pure metal, bi-metallic, composite, etc.), and each of the bipolar pulses may includes applying a negative pulse (e.g., with high power and short duration) to the metal target to dislodge metal atoms, and applying a positive pulse to the metal target to accelerate the metal atoms towards the nonmetal etch mask. Other configurations may of course exist, such as multi-target systems, etc. Various other pulses may be included, such as other series of pulses interspersed into the series of bipolar pulses. One example is a series of negative pulses (e.g., of lower power and/or longer duration than the negative pulses of the bipolar pulses). Another example is a series of alternating current (AC) pulses, that can be included before, after, or even in the middle of the bipolar pulses.

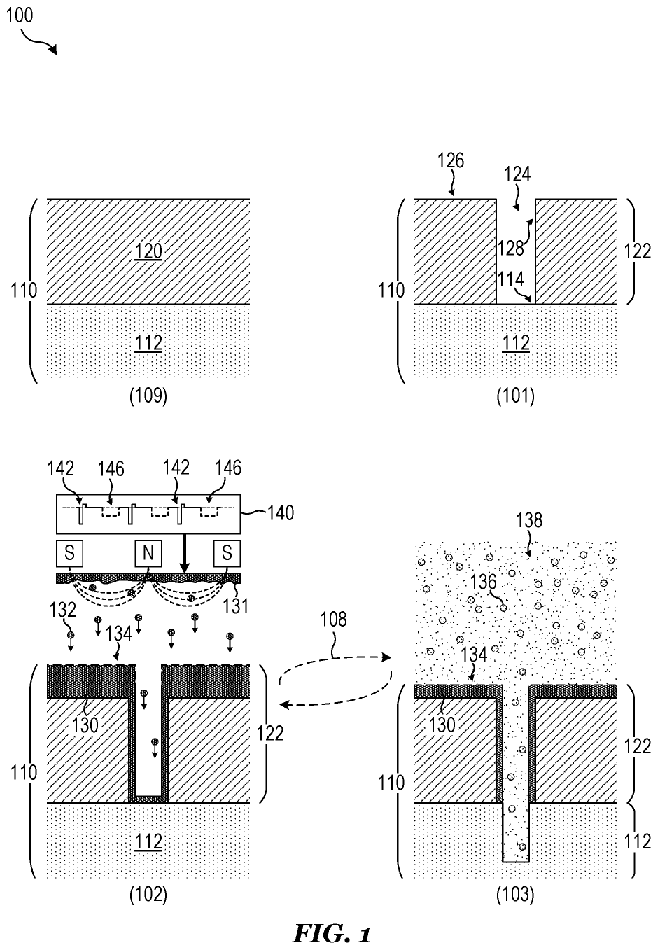

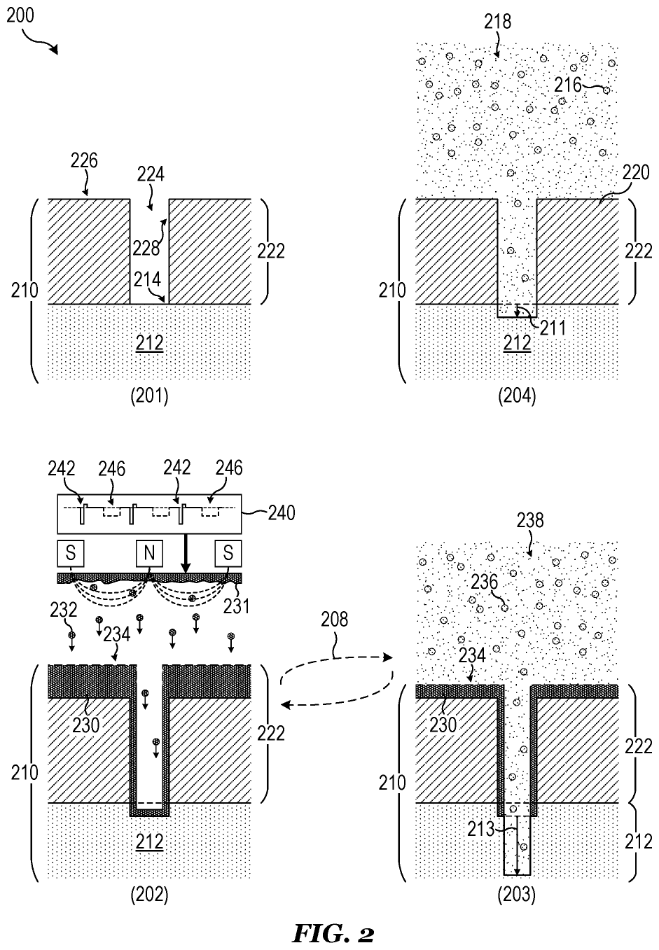

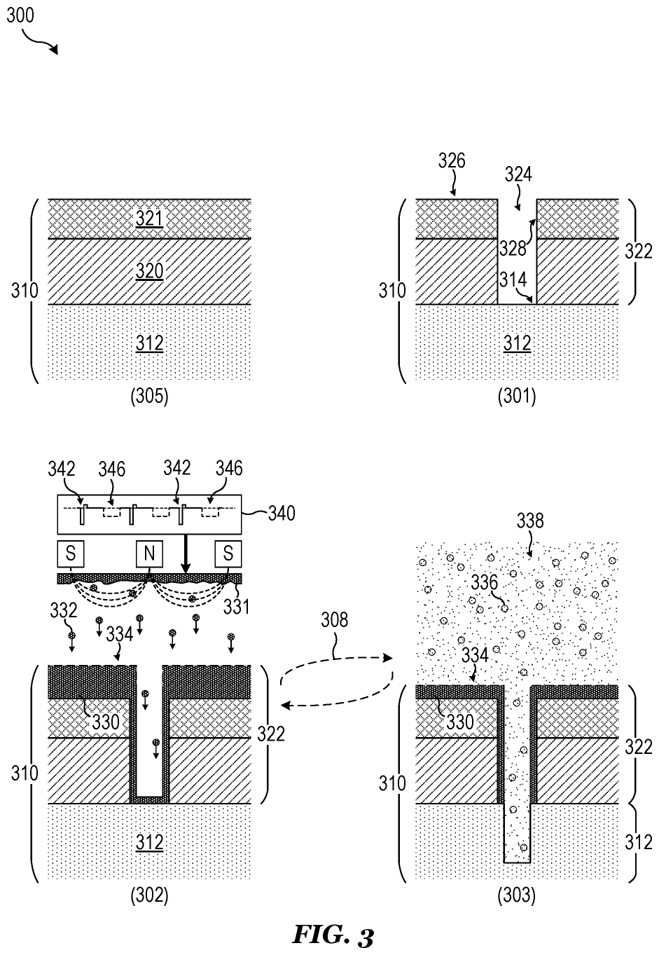

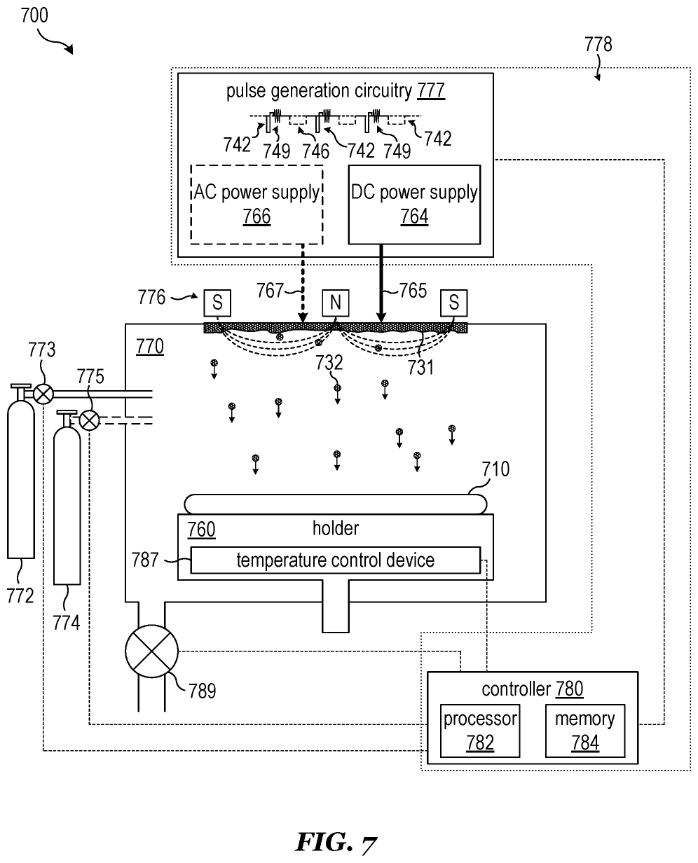

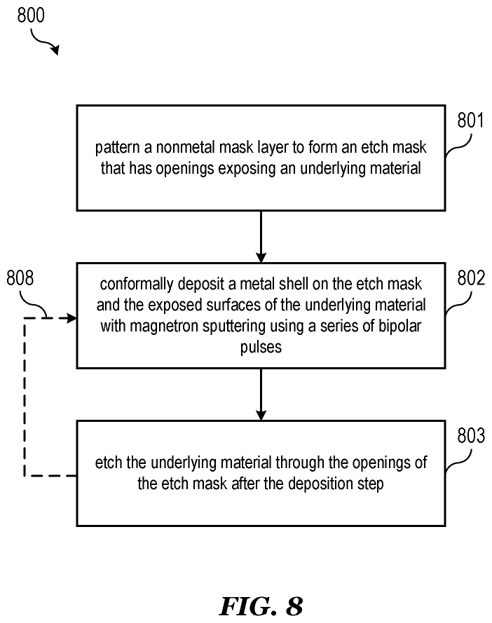

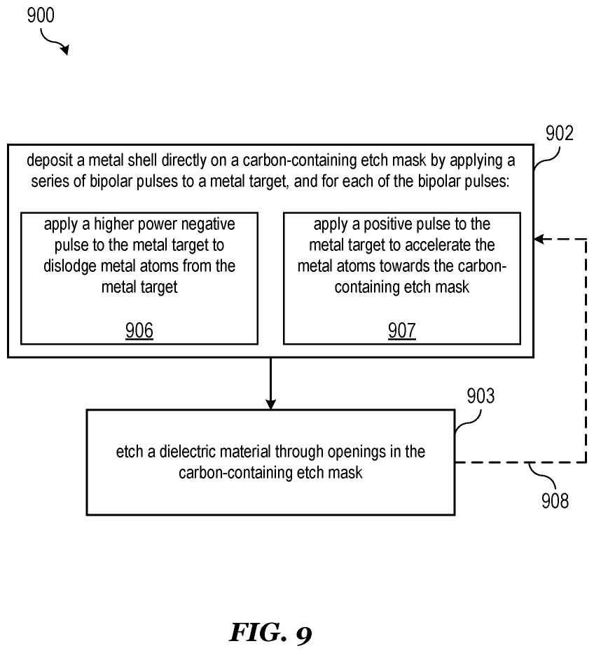

Embodiments provided below describe various systems and methods for metal encapsulation of an etch mask used during an etching process, and in particular embodiments, to etching processes that accomplish metal encapsulation of the etch mask using a metal shell deposited using a series of bipolar pulses. The following description describes the embodiments. FIG. 1 is used to describe an example etching process. Two specific examples of the etching process of FIG. 1 are described using FIGS. 2 and 3. Three qualitative timing diagrams of series of bipolar pulses that may correspond with bipolar pulses of described etching processes are described using FIGS. 4-6. An example bipolar pulsed magnetron sputtering system that may be used to perform the described etching processes is described using FIG. 7 while FIGS. 8 and 9 are used to described two example methods of etching.

FIG. 1 schematically illustrates an example etching process that includes patterning step, a deposition step, and an etch step where a continuous metal shell is deposited using a series of bipolar pulses during the deposition step in accordance with embodiments of the invention.

Referring to FIG. 1, an etching process 100 includes a substrate 110 in an initial state 109 where a nonmetal mask layer 120 is formed over an underlying material 112. The substrate 110 may be any suitable substrate, such as an insulating, conducting, or semiconducting substrate with one or more layers disposed thereon. For example, the underlying material 112 may be supported by a semiconductor wafer, such as a silicon wafer, and include various layers, structures, and devices (e.g., forming integrated circuits). In one embodiment, substrate 110 includes silicon. In another embodiment, the substrate 110 includes silicon germanium (SiGe). In still another embodiment, the substrate 110 includes gallium arsenide (GaAs). Of course, many other suitable materials, semiconductor or otherwise, may be included in the substrate 110 as may be apparent to those of skill in the art.

The underlying material 112 may be any material, but is a dielectric material in one embodiment. The dielectric material may be any suitable material or combination of materials that behaves as an electrical dielectric in the context of a given application (relative to materials behaving as semiconductors or conductors, for example). In various embodiments, the underlying material 112 includes an oxide material (e.g., thick oxide), and the underlying material 112 includes silicon dioxide (SiO₂) in one embodiment. In some embodiments, the underlying material 112 includes a nitride material, and the underlying material 112 includes silicon nitride (Si₃N₄) in one embodiment. Of course, other classes of dielectric material may also be included in the underlying material 112, such as an oxynitride material (e.g., silicon oxynitride (SiOₓN_{y}), and others). The underlying material 112 may include more than one type of material. In some specific applications, such as HARC etches, the underlying material 112 may be a stack of several layers of dielectric material. One specific example is an ONON stack, which includes multiple oxide layers (e.g., SiO₂) separated by nitride layers (e.g., Si₃N₄). Another example is an OPOP stack, which includes multiple oxide layers (e.g., SiO₂) separated by polysilicon layers.

The nonmetal mask layer 120 is then patterned during a patterning step 101 to form an etch mask 122. The etch mask 122 includes openings 124 that expose surfaces 114 of the underlying material 112 (i.e., so that a desired pattern may be transferred to the underlying material 112 in a subsequent etch step). The openings 124 alter the original upper surface (e.g., a substantially planar initial surface) to create upper surfaces 126 and sidewalls 128 forming the openings 124.

The etch mask 122 may be any suitable mask that is configured to protect regions of the underlying material 112 while allowing the underlying material 112 to be etched through the openings 124 during the etching process 100. In various embodiments, the etch mask 122 is a hardmask. The etch mask 122 may be electrically conductive, semiconducting, or insulating, but is formed (at least in part) from the nonmetal mask layer 120. In some embodiments, the etch mask 122 is a carbon-containing mask, and the etch mask 122 is an ACL mask in one embodiment. Other types of carbon-containing mask include SoC masks, diamond-like carbon masks, PR masks, and others. In other embodiments, the etch mask 122 is a silicon-containing mask, such as polysilicon, silicon nitride, silicon oxide, etc. Of course, many other mask materials may be used.

In a deposition step 102, pulsed DC power 140 is applied to a metal target 131 in the form of a series of bipolar pulses 142 to deposit a metal shell 130 on the etch mask 122 (and the exposed surfaces 114 of the underlying material 112). Each of the series of bipolar pulses 142 includes both a positive pulse and a negative pulse that are applied to the metal target 131 (e.g., not to a separate ring electrode or the substrate holder, although pulses to other such electrodes may also be included). For example, the series of bipolar pulses 142 may dislodge metal atoms 132 from the metal target 131 and accelerate them towards the etch mask 122 (such as with low energy to allow efficient deposition of the metal material to form the metal shell 130). Positive pulses (and AC pulses) may also ionize neutral metal and other neutral gas atoms/species in the gas phase, which may increase the ratio of ions:to neutrals.

The metal shell 130 may be a pure metal material (such as a tungsten shell), or may include a metal material. In various embodiments, the metal shell 130 includes a metal component, some examples of which include a metal nitride, a metal oxide, a metal carbide, a metal silicide, a metal silicon nitride, a metal boride, a metal boronitride, and others. In some embodiments, the metal shell 130 includes tungsten, and the metal shell 130 is pure tungsten in one embodiment (e.g., deposited as such, but of course some additional components may be present from the adjacent layers, or introduced in other process steps, or be introduced as small amounts of contamination, etc.). Some embodiments of the metal shell 130 include molybdenum (Mo), and the metal shell 130 is pure molybdenum in one embodiment. Other possible metals that may be included in the metal shell 130 include, but are not limited to, vanadium (V), ruthenium (Ru), and titanium (Ti). In some cases, the specific application where the metal shell 130 is utilized may impact the possible choice of material, such as front end of line (FEOL) versus back end of line (BEOL), one example of which may be the ability to use titanium in BEOL applications.

An optional series of negative pulses 146 may also be included in (i.e., interspersed into) the series of bipolar pulses 142 which may have the advantage of increasing the deposition rate at the upper surfaces 126 of the etch mask 122 relative to the deposition rate at the sidewalls 128 of the etch mask 122 (e.g., when it is desirable to provide greater protection of the upper surfaces 126 while depositing enough on the sidewalls 128 to protect the sidewalls, but not so much as to adversely affect the etch profile). When the upper surface deposition rate is increased relative to the sidewall deposition rate, an optional preferential deposition 134 occurs at the upper surfaces 126 (i.e., additional metal atoms 132 deposit and become part of the metal shell 130). That is, the metal shell 130 is a continuous metal shell, and additional thickness of the metal shell may or may not exist at the upper surfaces 126. When the metal shell 130 is deposited substantially evenly on all surfaces, the metal shell 130 may be considered conformal, while preferential deposition on the upper surfaces 126 result in a non-conformal film (that is still continuous).

Then, in an etch step 103, an etchant gas 136 (which may be a mixture of gases) is provided and a plasma 138 is formed by exciting the etchant gas 136 (also referred to as igniting the plasma 138). The plasma 138 is used to etch the underlying material 112 through the openings 124 using the etch mask 122 (including the metal shell 130 with or without the optional preferential deposition 134). In the specific example shown, the optional preferential deposition 134 advantageously offers increased protection of the upper surfaces 126, which may etch faster (e.g., because the etch step employs an anisotropic etching technique, such as to create HAR features in the underlying material 112). Optionally, the deposition step 102 and the etch step 103 may be repeated as a cycle 108, such as to replenish the metal shell 130 before it is fully etched away and thereby advantageously protecting the etch mask 122 while continuing to etch the underlying material 112.

FIG. 2 schematically illustrates another example etching process that includes patterning step, a deposition step, and an etch step, where a pre-etch step is also included in accordance with embodiments of the invention. The etching process of FIG. 2 may be a specific implementation of other etching processes described herein such as the etching process of FIG. 1, for example. Similarly labeled elements may be as previously described.

Referring to FIG. 2, an etching process 200 includes a substrate 210 where a carbon-containing mask layer 220 is formed over a dielectric material 212. It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system. The carbon-containing mask layer 220 is a specific example of a nonmetal mask layer while the dielectric material 212 is a specific example of an underlying material, but of course these could be replaced with other materials discussed elsewhere.

The carbon-containing mask layer 220 is then patterned during a patterning step 201 to form an etch mask 222. The etch mask 222 includes openings 224 that expose surfaces 214 of the dielectric material 212 creating upper surfaces 226 and sidewalls 228 of the carbon-containing mask layer 220. Then, a pre-etch step 204 of etching the dielectric material 212 to a pre-etch depth 211 through the openings 224 of the etch mask 222 is performed (i.e., before a metal shell 230 is deposited in a deposition step 202). For example, a pre-etchant gas 216 may be provided that is excited to form a pre-etch plasma 218. During the pre-etch step 204, a recess is formed in the dielectric material 212 before the metal shell 230 is deposited.

In the deposition step 202, pulsed DC power 240 is applied to a metal target 231 in the form of a series of bipolar pulses 242 to deposit the metal shell 230 on the etch mask 222 (and the exposed surfaces 214 of the dielectric material 212, which are now at the bottom of the recesses and include sidewalls, as shown). For example, the series of bipolar pulses 242 may dislodge metal atoms 232 from the metal target 231 and accelerate them towards the etch mask 222. An optional series of negative pulses 246 may also be used to increase the deposition rate at the upper surfaces 226 of the etch mask 222 relative to the deposition rate at the sidewalls 228 of the etch mask 222 resulting in an optional preferential deposition 234 at the upper surfaces 226.

An etchant gas 236 is then provided during an etch step 203, and a plasma 238 is formed by exciting the etchant gas 236. The plasma 238 is used to etch the dielectric material 212 to an etch depth 213 (which may be the same or different from the pre-etch depth 211) through the openings 224 using the etch mask 222 (including the metal shell 230 with or without the optional preferential deposition 234). While in this example, the pre-etchant gas 216 and the pre-etch plasma 218 are shown as different from the etchant gas 236 and the plasma 238 to indicate that this may be the case, these may also be the same for the pre-etch step 204 and the etch step 203. Optionally, the deposition step 202 and the etch step 203 may be repeated as a cycle 208, such as to replenish the metal shell 230 before it is fully etched away and thereby advantageously protecting the etch mask 222 while continuing to etch the dielectric material 212.

FIG. 3 schematically illustrates still another example etching process that includes patterning step, a deposition step, and an etch step, where a CVD step is also included in accordance with embodiments of the invention. The etching process of FIG. 3 may be a specific implementation of other etching processes described herein such as the etching process of FIG. 1, for example. Similarly labeled elements may be as previously described.

Referring to FIG. 3, an etching process 300 includes a substrate 310 where a carbon-containing mask layer 320 is formed over a dielectric material 312. In this specific implementation of the etching process 100, a metal-containing layer 321 is formed over the carbon-containing mask layer 320 in a CVD deposition step 305 that may also include processes that utilize additional techniques in addition to CVD, such as CVD and PVD, which may also be referred to as reactive sputtering. The metal-containing layer 321 may be any metal-containing material, such as the various materials that may be used to form a metal shell 330 in a later deposition step 302. In some embodiments, the metal-containing layer 321 is the same material as the metal shell 330. In other embodiments, the metal-containing layer 321 has a different material composition than the metal shell 330. Because the metal-containing layer 321 is formed using a CVD process, the film properties of the metal-containing layer 321 may differ from that of the metal shell 330 (such as the metal-containing layer 321 being rougher than the metal shell 330, for example).

The carbon-containing mask layer 320 (including the metal-containing layer 321) is then patterned during a patterning step 301 to form an etch mask 322. The etch mask 322 includes openings 324 that expose surfaces 314 of the dielectric material 312 creating upper surfaces 326 and sidewalls 328 of the carbon-containing mask layer 320. In the deposition step 302, pulsed DC power 340 is applied to a metal target 331 in the form of a series of bipolar pulses 342 to deposit the metal shell 330 on the etch mask 322 and the exposed surfaces 314 of the dielectric material 312. For example, the series of bipolar pulses 342 may dislodge metal atoms 332 from the metal target 331 and accelerate them towards the etch mask 322. An optional series of negative pulses 346 may also be used to increase the deposition rate at the upper surfaces 326 of the etch mask 322 relative to the deposition rate at the sidewalls 328 of the etch mask 322 resulting in an optional preferential deposition 334 at the upper surfaces 326.

An etchant gas 336 is then provided during an etch step 303, and a plasma 338 is formed by exciting the etchant gas 336. The plasma 338 is used to etch the dielectric material 312 through the openings 324 using the etch mask 322 (including the metal shell 330 with or without the optional preferential deposition 334). Optionally, the deposition step 302 and the etch step 303 may be repeated as a cycle 308, such as to replenish the metal shell 330 before it is fully etched away and thereby advantageously protecting the etch mask 322 while continuing to etch the dielectric material 312.

FIG. 4 illustrates a qualitative timing diagram of a series of bipolar pulses that may be used during example etching processes described herein, such as the etching processes of FIGS. 1-3, for example, where each bipolar pulse includes a negative pulse and a positive pulse in accordance with embodiments of the invention. Similarly labeled elements may be as previously described.

Referring to FIG. 4, a timing diagram 400 qualitatively shows a series of bipolar pulses that each include a higher power negative pulse 443 and a positive pulse 444. The parameters of the higher power negative pulse 443 and the positive pulse 444 may be adjusted as desired, including higher power pulse width 445, positive pulse width 447, negative voltage 453, and positive voltage 454, as well as spacing of the pulses, using one or both of an intrapulse delay 441 and an interpulse delay 448. Moreover, the parameters may be changed during the series of bipolar pulses (which may be used to tune various properties of the deposited metal shell, adjust to dynamically changing processing conditions, etc.).

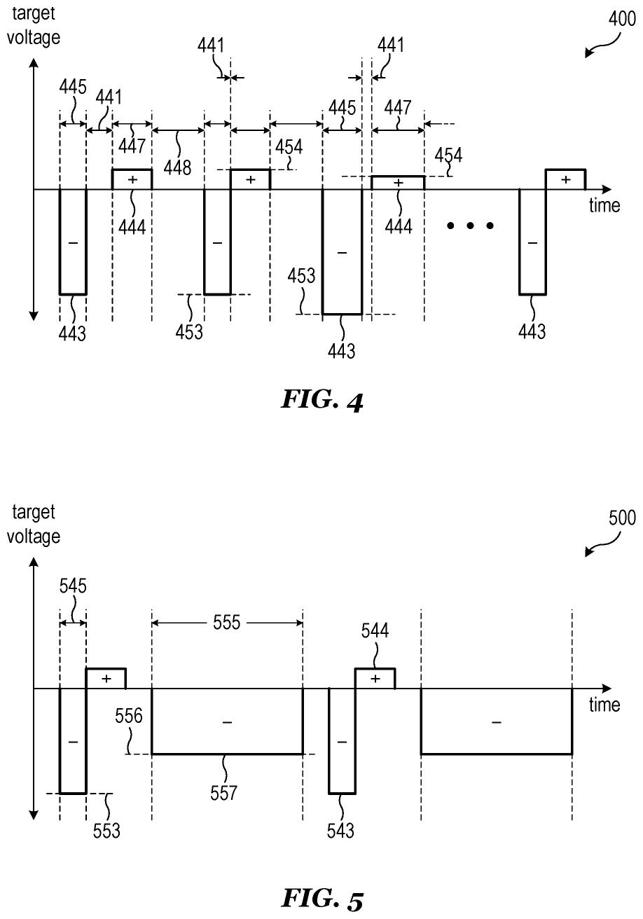

FIG. 5 illustrates a qualitative timing diagram of a series of bipolar pulses that may be used during example etching processes described herein, where a series of negative pulses is interspersed into the series of bipolar pulses e in accordance with embodiments of the invention. The qualitative timing diagram of FIG. 5 may show a specific implementation of other series of bipolar pulses described herein such as the other series of bipolar pulses of FIG. 4, for example. Similarly labeled elements may be as previously described.

Referring to FIG. 5, a timing diagram 500 qualitatively shows a series of bipolar pulses that each include a higher power negative pulse 543 and a positive pulse 544. In this specific example the series of bipolar pulses also includes a series of negative pulses interspersed into the series of bipolar pulses (each of the negative pulses being a lower power negative pulse 557). While not required, in various embodiments, each higher power negative pulse 543 may have a higher negative voltage 553 than the lower negative voltage 556 of each lower power negative pulse 557. Also, (as a contrast to the “impulse” technique of the series of bipolar pulses), a lower power pulse width 555 of each of the lower power negative pulse 557 may be longer in duration than a higher power pulse width 545 of each of the higher power negative pulse 543. It should also be noted that more than one bipolar pulse may be included between consecutive instances of the lower power negative pulse 557 (or vice versa). Additionally, the various parameters of any of the pulses or delays between pulses may be adjusted as desired.

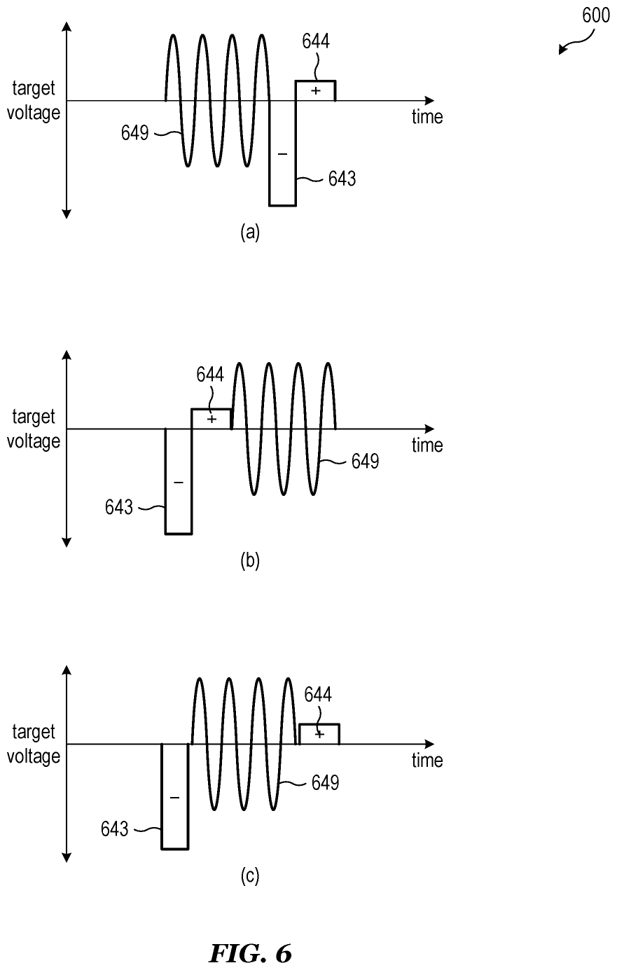

FIG. 6 illustrates a qualitative timing diagram of a series of bipolar pulses that may be used during example etching processes described herein, where a series of AC pulses is interspersed into the series of bipolar pulses accordance with embodiments of the invention. The qualitative timing diagram of FIG. 6 may show a specific implementation of other series of bipolar pulses described herein such as the other series of bipolar pulses of FIG. 4, for example. Similarly labeled elements may be as previously described.

Referring to FIG. 6, a timing diagram 600 qualitatively shows a series of bipolar pulses that each include a higher power negative pulse 643 and a positive pulse 644. In this specific example the series of bipolar pulses also includes a series of AC pulses interspersed into the series of bipolar pulses (each of the AC pulses being an AC pulse 649 such as in the high frequency (HF) range, of any desired waveform, but shown as a sinusoidal waveform in this example). The series of AC pulses may be inserted at any location relative to the series of bipolar pulses. For example, as shown in the graph (a), the AC pulse 649 may be included before the higher power negative pulse 643 of a bipolar pulse (with some delay, if desired). In another example shown in graph (b), the AC pulse 649 may be included after the positive pulse 644 (again with some delay, if desired). In some embodiments, the higher power negative pulse 643 and the positive pulse 644 of a bipolar pulse may even be split, as shown in graph (c). Of course, an optional series of negative pulses may also be included along with the series of AC pulses.

The series of AC pulses may have the advantage of promoting reactive sputtering without including (or including less) a reactive gas. When a reactive gas, such as nitrogen (N₂), oxygen (O₂), methane (CH₄), etc. is included, the series of AC pulses may enhance the reactive sputtering effect.

FIG. 7 illustrates an example bipolar pulsed magnetron sputtering system that can be used to perform example etching processes described herein, where the system includes pulse generation circuitry configured to generate a series of bipolar pulses in accordance with embodiments of the invention. The system of FIG. 7 may be used to perform any of the methods or processes described herein, such as the etching processes of FIGS. 1-3 and the methods of FIGS. 8 and 9, for example. Similarly labeled elements may be as previously described.

Referring to FIG. 7, a bipolar pulsed magnetron sputtering system 700 includes a chamber 770 and a metal target 731 disposed in the chamber 770. The chamber 770 may be any suitable type of processing chamber, including a multipurpose chamber allowing both deposition and etching processes to be performed therein. A holder 760 (e.g., a chuck electrode) is configured to support a substrate 710 in the chamber 770. A plasma gas source 772 is fluidically coupled to the chamber 770 through one or more valve, such as a plasma gas valve 773. An optional reactive gas source 774 may also be fluidically coupled to the chamber 770 through one or more valves, such as a optional reactive gas valve 775. For example, the reactive gas may be included to promote reactive sputtering. Some example reactive gases include nitrogen (N₂), oxygen (O₂), methane (CH₄), and others.

Processing circuitry 778, which may include a pulse generation circuitry 777 and a controller 780, is operatively coupled to the metal target 731, the plasma gas valve 773, and the optional reactive gas valve 775 (when included). The processing circuitry 778 may be configured to provide the plasma gas (and the reactive gas) into the chamber 770 and instruct the pulse generation circuitry 777 to generate a series of bipolar pulses 742 (along with an optional series of negative pulses 746 and/or an optional series of AC pulses 749 in some embodiments). For example, a DC power supply 764 may provide DC power 765 to the metal target 731 in the form of the series of bipolar pulses 742 (as well as the optional series of negative pulses 746, when included). Alternatively, a separate power supply may be used to supply the optional series of negative pulses 746.

Similarly, an optional AC power supply 766 may be included to provide AC power 767 in the form of the optional series of AC pulses 749. The applied pulses are configured to dislodge metal atoms 732 from the metal target 731 (e.g., using atoms of the plasma gas). A magnetic array 776 is included to confine charged particles in fields near the metal target 731. The positive pulses of the series of bipolar pulses may temporarily expand the plasma sheath toward the substrate 710 (and expel metal atoms from confinement, accelerating the metal atoms (i.e., metal ions) toward the substrate 710).

Various other optional components may also be included, such as an optional temperature control device 787 (to adjust the temperate of the substrate 710 above or below the equilibrium temperature at the substrate 710). Other examples may include a source power supply for generating the plasma of an etch step, a bias power supply for applying a bias to the holder 760, one or more monitoring devices, such as a temperature monitor, and others. An exhaust 789 is included to evacuate the chamber 770 to the desired vacuum level and may also be operatively coupled to the controller 780.

When included the controller 780 includes a processor 782 and a memory 784 (i.e., a non-transitory computer-readable medium) that stores a program including instructions that, when executed by the processor 782, may perform various steps of an etching process. For example, the memory 784 may have volatile memory (e.g., random access memory (RAM)) and non-volatile memory (e.g., flash memory). Alternatively, the program may be stored in physical memory at a remote location, such as in cloud storage. The processor 782 may be any suitable processor, such as the processor of a microcontroller, a general-purpose processor (such as a central processing unit (CPU), a microprocessor, a field-programmable gate array (FPGA), an application-specific integrated circuit (ASIC), and others.

While at least the deposition steps described herein may be performed by the bipolar pulsed magnetron sputtering system 700 in the chamber 770, the etch steps and patterning steps may be performed in a different chamber (but still part of the bipolar pulsed magnetron sputtering system 700. However, in some cases the chamber 770 may be configured to perform the deposition steps in addition to one or both of the patterning steps and the etch steps.

FIG. 8 illustrates a flowchart of an example method of etching an underlying material that includes a patterning step, a deposition step, and an etch step in accordance with embodiments of the invention. The method of FIG. 8 may be combined with other methods and performed using the systems and apparatuses as described herein. For example, the method of FIG. 8 may be combined with any of the embodiments of FIGS. 1-7 and 9. Although shown in a logical order, the arrangement and numbering of the steps of FIG. 8 are not intended to be limited. The method steps of FIG. 8 may be performed in any suitable order or concurrently with one another as may be apparent to a person of skill in the art.

Referring to FIG. 8, a method 800 includes a patterning step 801 of patterning a nonmetal mask layer (e.g., a silicon-containing layer like silicon nitride, a carbon-containing material like an ACL, etc.) to form an etch mask comprising openings exposing an underlying material. In a deposition step 802, a continuous metal shell (e.g., a metal-containing material, metallic material, or a pure metal, such as a tungsten shell) is deposited on the etch mask and exposed surfaces of the underlying material using a series of bipolar pulses. Specifically, a bipolar pulsed magnetron sputtering technique is employed that uses the series of bipolar pulses to deposit the metal shell. The underlying material is then etched through the openings of the etch mask during an etch step 803. Optionally, the deposition step 802 and the etch step 803 may be repeated as part of a cycle 808 to continue depositing the metal shell and etching the underlying material.

As previously described, various other steps may also be included in the method 800. For example, depositing a metal-containing layer on the nonmetal mask layer using CVD before the patterning step 801. In this case, the patterning step 801 would also include patterning the metal-containing layer as part of the etch mask. The metal shell would be deposited over the metal-containing layer as well as the nonmetal mask (e.g., to decrease surface roughness of the metal-containing layer). The method 800 may also include etching the underlying material through the openings of the etch mask before the deposition step 802 (a breakthrough etch being one example).

The details of the series of bipolar pulses may be determined according to the detail of a given application. For example, in some embodiments, the deposition step 802 also includes interspersing a series of negative pulses into the series of bipolar pulses to preferentially deposit the metal shell on upper surfaces of the etch mask. In one embodiment, the series of bipolar pulses having a higher negative voltage than the series of negative pulses (i.e., the negative pulses of the bipolar pulses are more negative than the added negative pulses). Additionally or alternatively, as series of AC pulses may be interspersed into the series of bipolar pulses, such as to promote reactive sputtering while depositing the metal shell.

FIG. 9 illustrates a flowchart of an example method of etching a dielectric material that includes a deposition step and an etch step in accordance with embodiments of the invention. The method of FIG. 9 may be combined with other methods and performed using the systems and apparatuses as described herein. For example, the method of FIG. 9 may be combined with any of the embodiments of FIGS. 1-8. Although shown in a logical order, the arrangement and numbering of the steps of FIG. 9 are not intended to be limited. The method steps of FIG. 9 may be performed in any suitable order or concurrently with one another as may be apparent to a person of skill in the art.

Referring to FIG. 9, a method 900 includes a deposition step 902 of depositing a continuous metal shell (e.g., a metal-containing material, metallic material, or a pure metal, such as a tungsten shell) on a carbon-containing etch mask (e.g., an ACL) by applying a series of bipolar pulses to a metal target. The deposition step 902 includes a higher power negative pulse 906 and a positive pulse 907. The higher power negative pulse 906 is applied to the metal target to dislodge atoms from the metal target while the positive pulse 907 is applied to metal target to accelerate the metal atoms (i.e., positive metal ions) towards the carbon-containing mask. A dielectric material (e.g., silicon oxide) is then etched through the openings of the carbon-containing mask during an etch step 903. Optionally, the deposition step 902 and the etch step 903 may be repeated as part of a cycle 908 to continue continuously depositing the metal shell and etching the dielectric material.

Similar to the above, other steps may also be included in the method 900. For example, the method 900 may also include etching the underlying material through the openings of the etch mask before the deposition step 902. During the deposition step 902, the deposition rate at upper surfaces of the carbon-containing mask may be increased relative to the deposition rate at sidewalls of the carbon-containing mask by interspersing a series of lower power negative pulses into the series of bipolar pulses. Additionally or alternatively, reactive sputtering may be promoted during the deposition step 902 by interspersing a series of AC pulses into the series of bipolar pulses. The AC pulses may of course be included at any desired location, including both between bipolar pulses and between the negative pulse and positive pulse of each bipolar pulse (i.e., for each of the bipolar pulses, an AC pulse of the series of AC pulses may be applied to the metal target after the higher power negative pulse and before the positive pulse).

Example embodiments of the invention are summarized here. Other embodiments can also be understood from the entirety of the specification as well as the claims filed herein.

Example 1. A method of etching an underlying material, the method including: performing a patterning step of patterning a nonmetal mask layer to form an etch mask including openings exposing the underlying material; performing a deposition step of depositing a metal shell on the etch mask and exposed surfaces of the underlying material with magnetron sputtering using a series of bipolar pulses; and performing an etch step of etching the underlying material through the openings of the etch mask after the deposition step.

Example 2. The method of example 1, further including: repeating the deposition step and the etch step as part of a cycle to continue depositing the metal shell and etching the underlying material.

Example 3. The method of one of examples 1 and 2, further including: depositing a metal-containing layer on the nonmetal mask layer using chemical vapor deposition before the patterning step, where the patterning step further includes patterning the metal-containing layer as part of the etch mask, and where depositing the metal shell during the deposition step decreases surface roughness of the metal-containing layer.

Example 4. The method of one of examples 1 to 3, further including: etching the underlying material through the openings of the etch mask before the deposition step.

Example 5. The method of one of examples 1 to 4, where the deposition step further includes interspersing a series of negative pulses into the series of bipolar pulses to preferentially deposit the metal shell on upper surfaces of the etch mask, the series of bipolar pulses having a higher negative voltage than the series of negative pulses.

Example 6. The method of one of examples 1 to 5, where the metal shell is a tungsten shell.

Example 7. The method of one of examples 1 to 6, where the nonmetal mask layer is a carbon-containing mask layer.

Example 8. The method of example 7, where the carbon-containing mask layer is an amorphous carbon layer (ACL).

Example 9. A method of etching a dielectric material, the method including: performing a deposition step of depositing a metal shell directly on a carbon-containing etch mask by applying a series of bipolar pulses to a metal target, each of the bipolar pulses including applying a higher power negative pulse to the metal target to dislodge metal atoms therefrom, and applying a positive pulse to the metal target to accelerate the metal atoms towards the carbon-containing etch mask; and performing an etch step of etching the dielectric material through openings in the carbon-containing etch mask.

Example 10. The method of example 9, further including: repeating the deposition step and the etch step as part of a cycle to continue depositing the metal shell and etching the dielectric material.

Example 11. The method of one of examples 9 and 10, further including: etching the dielectric material through the openings in the carbon-containing etch mask before the deposition step.

Example 12. The method of one of examples 9 to 11, further including: increasing an upper surface deposition rate of the metal shell relative to a sidewall deposition rate of the metal shell by interspersing a series of lower power negative pulses into the series of bipolar pulses.

Example 13. The method of one of examples 9 to 12, further including: promoting reactive sputtering while depositing the metal shell by interspersing a series of alternating current (AC) pulses into the series of bipolar pulses.

Example 14. The method of example 13, where, for each of the bipolar pulses, an AC pulse of the series of AC pulses is applied to the metal target after the higher power negative pulse and before the positive pulse.

Example 15. The method of one of examples 9 to 14, where the metal shell is tungsten, the carbon-containing etch mask is an amorphous carbon layer (ACL), and the dielectric material is silicon oxide.

Example 16. A bipolar pulsed magnetron sputtering system including: a chamber; a metal target disposed in the chamber; a holder configured to support a substrate including a nonmetal etch mask; pulse generation circuitry electrically coupled to the metal target and the holder, the pulse generation circuitry being configured to generate a series of bipolar pulses; and processing circuitry configured to deposit a metal shell directly on the nonmetal etch mask and exposed surfaces of an underlying material using the series of bipolar pulses.

Example 17. The system of example 16, where, for each of the bipolar pulses, the processing circuitry is further configured to apply a higher power negative pulse to the metal target to dislodge metal atoms therefrom, and apply a positive pulse to the metal target to accelerate the metal atoms towards the nonmetal etch mask.

Example 18. The system of example 17, where the processing circuitry is further configured to intersperse a series of lower power negative pulses into the series of bipolar pulses to increase an upper surface deposition rate of the metal shell relative to a sidewall deposition rate of the metal shell.

Example 19. The system of one of examples 16 to 18, further including: an alternating current (AC) power supply operatively coupled to the pulse generation circuitry, where the pulse generation circuitry is further configured to generate a series of AC pulses, and where the processing circuitry is further configured to intersperse the series of AC pulses into the series of bipolar pulses to promote reactive sputtering while depositing the metal shell.

Example 20. The system of one of examples 16 to 19, where the metal target is a tungsten target.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of etching an underlying material, the method comprising:
performing a patterning step of patterning a nonmetal mask layer to form an etch mask comprising openings exposing the underlying material;
performing a deposition step of depositing a metal shell on the etch mask and exposed surfaces of the underlying material with magnetron sputtering using a series of bipolar pulses; and
performing an etch step of etching the underlying material through the openings of the etch mask after the deposition step.

2. The method of claim 1, further comprising:
repeating the deposition step and the etch step as part of a cycle to continue depositing the metal shell and etching the underlying material.

3. The method of claim 1, further comprising:
depositing a metal-containing layer on the nonmetal mask layer using chemical vapor deposition before the patterning step,
wherein the patterning step further comprises patterning the metal-containing layer as part of the etch mask, and
wherein depositing the metal shell during the deposition step decreases surface roughness of the metal-containing layer.

4. The method of claim 1, further comprising:
etching the underlying material through the openings of the etch mask before the deposition step.

5. The method of claim 1, wherein the deposition step further comprises interspersing a series of negative pulses into the series of bipolar pulses to preferentially deposit the metal shell on upper surfaces of the etch mask, the series of bipolar pulses having a higher negative voltage than the series of negative pulses.

6. The method of claim 1, wherein the metal shell is a tungsten shell.

7. The method of claim 1, wherein the nonmetal mask layer is a carbon-containing mask layer.

8. The method of claim 7, wherein the carbon-containing mask layer is an amorphous carbon layer (ACL).

9. A method of etching a dielectric material, the method comprising:
performing a deposition step of depositing a metal shell directly on a carbon-containing etch mask by applying a series of bipolar pulses to a metal target, each of the bipolar pulses comprising
applying a higher power negative pulse to the metal target to dislodge metal atoms therefrom, and
applying a positive pulse to the metal target to accelerate the metal atoms towards the carbon-containing etch mask; and
performing an etch step of etching the dielectric material through openings in the carbon-containing etch mask.

10. The method of claim 9, further comprising:
repeating the deposition step and the etch step as part of a cycle to continue depositing the metal shell and etching the dielectric material.

11. The method of claim 9, further comprising:
etching the dielectric material through the openings in the carbon-containing etch mask before the deposition step.

12. The method of claim 9, further comprising:
increasing an upper surface deposition rate of the metal shell relative to a sidewall deposition rate of the metal shell by interspersing a series of lower power negative pulses into the series of bipolar pulses.

13. The method of claim 9, further comprising:
promoting reactive sputtering while depositing the metal shell by interspersing a series of alternating current (AC) pulses into the series of bipolar pulses.

14. The method of claim 13, wherein, for each of the bipolar pulses, an AC pulse of the series of AC pulses is applied to the metal target after the higher power negative pulse and before the positive pulse.

15. The method of claim 9, wherein the metal shell is tungsten, the carbon-containing etch mask is an amorphous carbon layer (ACL), and the dielectric material is silicon oxide.

16. A bipolar pulsed magnetron sputtering system comprising:
a chamber;
a metal target disposed in the chamber;
a holder configured to support a substrate comprising a nonmetal etch mask;
pulse generation circuitry electrically coupled to the metal target and the holder, the pulse generation circuitry being configured to generate a series of bipolar pulses; and
processing circuitry configured to deposit a metal shell directly on the nonmetal etch mask and exposed surfaces of an underlying material using the series of bipolar pulses.

17. The system of claim 16, wherein, for each of the bipolar pulses, the processing circuitry is further configured to
apply a higher power negative pulse to the metal target to dislodge metal atoms therefrom, and
apply a positive pulse to the metal target to accelerate the metal atoms towards the nonmetal etch mask.

18. The system of claim 17, wherein the processing circuitry is further configured to
intersperse a series of lower power negative pulses into the series of bipolar pulses to increase an upper surface deposition rate of the metal shell relative to a sidewall deposition rate of the metal shell.

19. The system of claim 16, further comprising:
an alternating current (AC) power supply operatively coupled to the pulse generation circuitry,
wherein the pulse generation circuitry is further configured to generate a series of AC pulses, and
wherein the processing circuitry is further configured to intersperse the series of AC pulses into the series of bipolar pulses to promote reactive sputtering while depositing the metal shell.

20. The system of claim 16, wherein the metal target is a tungsten target.
